(19) United States
(12) Patent Application Publication
(10) Pub. No.: US 2010/0173229 A1
(43) Pub. Date: Jul. 8, 2010

(54) SHRINKABLE LABEL HAVING A HOLOGRAM LAYER AND CONTAINER WITH THE LABEL

(75) Inventors: Eiji Hikida, Osaka-shi Osaka (JP); Akiko Haga, Osaka-shi Osaka (JP); Tomotaka Ohshika, Osaka-shi Osaka (JP); Akira Shintani, Amagasaki-shi Hyogo (JP); Akira Miyazaki, Nabari-shi Mie (JP)

Correspondence Address: EDWARDS ANGELL PALMER & DODGE LLP, P.O. BOX 55874, BOSTON, MA, 02205, US

(73) Assignee: FUJI SEAL INTERNATIONAL, INC., Osaka (JP)

(21) Appl. No.: 12/452,644

(22) PCT Filed: Jul. 9, 2008
(86) PCT No.: PCT/JP2008/062389

§ 371 Date: Jan. 13, 2010

(30) Foreign Application Priority Data
Jul. 18, 2007 (JP) 2007-186724

(51) Int. Cl. G03F 7/00

(52) U.S. Cl. 430/2

(57) ABSTRACT

Provided is a shrinkable label having a hologram layer that suffers no whitening even after shrink processing with relatively large shrinkage. The label therefore fits even complicated dimensions of an article and, in addition, provides a superior holographic expression.

The shrinkable label includes a shrinkable film and a hologram layer present on or above at least one side of the shrinkable film. The hologram layer has been formed by curing a radically curable resin composition by the action of an active energy ray. The resin composition contains 45 to 95 percent by weight of an acrylic monomer and 5 to 55 percent by weight of a bifunctional or higher-functional urethane acrylate, based on the total amount of the acrylic monomer and the bifunctional or higher-functional urethane acrylate.

### TECHNICAL FIELD

The present invention relates to a shrinkable label having a hologram layer. More specifically, it relates to a shrinkable label that provides a sharp holographic expression even after shrink processing with relatively large deformation. It also relates to a container with the shrinkable label attached thereto.

### BACKGROUND ART

Labels each having a hologram (holographic labels) are currently used for the purpose typically of imparting a graphical design function or of preventing forgery. Known holographic labels generally employed are wrapping labels and tack labels which are prepared by applying or transferring a hologram foil to a base paper or a non-shrinkable plastic base film. These labels, however, are difficult to be in intimate contact with articles having irregular complicated dimensions (shapes), because they do not so satisfactorily fit such irregular complicated dimensions. Examples of the articles having irregular complicated dimensions include PET plastic bottles.

In contrast, some of holographic labels using heat-shrinkable base materials are improved in fitting ability (Patent Documents 1 to 3). These labels, however, are also wrapping labels each having a pressure-sensitive adhesive layer. When they are applied typically to dry cells, they shrink and deform only at upper and lower ends thereof so as to fit the dimensions of the dry cells at the upper and lower ends, but their bodies carrying a hologram hardly shrink.

Specifically, there has been obtained no holographic label which includes a hologram carried by a shrinkable film (especially by a tubular shrinkable label) that can fit complicated dimensions of bottles.

Patent Document 1: Japanese Unexamined Patent Application Publication (JP-A) No. 2003-177672

Patent Document 2: Japanese Unexamined Patent Application Publication (JP-A) No. 2003-330351

Patent Document 3: Japanese Unexamined Patent Application Publication (JP-A) No. 2004-230571

### DISCLOSURE OF INVENTION

### Problems to be Solved by the Invention

To fit such bottle dimensions, so-called “tubular shrinkable labels” have been used. These tubular (cylindrical) shrinkable labels undergo large shrinkage so as to fit the bottle dimensions. The present inventors attempted to adopt the known holographic labels typically to such tubular shrinkable labels, and, as a result, found that the hologram layer does not conform to or follow the shrinkage and suffers from problems such as whitening upon shrinkage. Independently, inks that can satisfactorily conform to shrink processing have been used for known tubular shrinkable labels (see, for example, PCT International Publication Number WO 2007/007803). The present inventors also attempted to adopt these inks to holographic labels and, as a result, found that the hologram is lost as a result of shrink processing.

Accordingly, an object of the present invention is to provide a shrinkable label having a hologram, which provides a holographic expression even when adopted to a tubular shrinkable label that undergoes relatively large shrinkage and which satisfactorily conforms to shrinkage. Another object of the present invention is to provide a container with a holographic label, as prepared by attaching the shrinkable label to the container.

### Means for Solving the Problems

After intensive investigations to achieve the objects, the present inventors have found that the use of a hologram layer prepared from a resin composition having a specific resinous formulation can give a shrinkable label that satisfactorily conforms to shrink processing with relatively large deformation and provides a sharp holographic expression even after the shrink processing. The present invention has been made based on these findings.

Specifically, the present invention provides, in an embodiment, a shrinkable label which includes a shrinkable film, and a hologram layer present on or above at least one side of the shrinkable film, in which the hologram layer is a cured article derived from a resin composition. The resin composition is radically curable by the action of an active energy ray and contains 45 to 95 percent by weight of one or more acrylic monomers and 5 to 55 percent by weight of one or more bifunctional or higher-functional urethane acrylates, based on the total amount of the acrylic monomers and the bifunctional or higher-functional urethane acrylates.

In the shrinkable label, the shrinkable film may have a percentage of thermal shrinkage (in hot water at 70° C. for 10 seconds) in its principal orientation direction of from 10% to 30% and may have a percentage of thermal shrinkage (in hot water at 80° C. for 10 seconds) in its principal orientation direction of from 30% to 70%.

The shrinkable label may have a shrinkage rate (in hot water at 80° C.) in its principal orientation direction of from 1% to 20% per 0.2 second.

The shrinkable label may have a shrinkage stress in its principal orientation direction of from 1.0 to 6.0 newtons per square millimeter (N/mm²), in which the shrinkage stress is determined while immersing 80% of a test piece of the shrinkable label in hot water at 80° C. for 10 seconds.

The shrinkable label may be a tubular shrinkable label.

In another embodiment, the present invention provides a container with a label, prepared by placing the shrinkable label around a container and allowing the label to shrink to thereby come into intimate contact with the container.

### ADVANTAGES

The shrinkable label according to an embodiment of the present invention suffers from neither whitening of the hologram layer upon shrinkage nor hologram loss even after shrink processing with relatively large shrinkage. The shrinkable label therefore exhibits both satisfactory shape conformity (dimensional conformity) and a sharp holographic expression even when applied to an article having complicated dimensions, and is thereby advantageous especially as a label typically for PET plastic bottles.

### BEST MODES FOR CARRYING OUT THE INVENTION

Some embodiments of the present invention will be illustrated in detail below.

A shrinkable label according to an embodiment of the present invention has a multilayer structure and includes a shrinkable film and, on or above at least one side thereof, a hologram layer. It should be noted, however, that the hologram layer does not have to spread over a whole side of the shrinkable label, and the shrinkable label has only to at least partially include a multilayer structure of the shrinkable film and the hologram layer. The shrinkable film and the hologram layer may lie on each other directly without the interposition of another layer or may lie over each other with the interposition of one or more other layers. Exemplary other layers include adhesive layers and anchor coat layers. Each of these layers may be a single layer or a multilayer including two or more layers.

### [Hologram Layer]

The hologram layer in the shrinkable label is formed by curing a resin composition that is curable by the action of an active energy ray. The hologram layer formed from such a resin composition that is curable by the action of an active energy ray is advantageously adoptable even to a base material, such as a shrinkable film, which thermally deforms upon usage. In contrast, a hologram layer formed from a heat-curable resin composition is unsuitable to be adopted to the base material which will thermally deform. Of active energy rays, the resin composition for the formation of the hologram layer is preferably curable by the action of an ultraviolet ray or near-ultraviolet ray. The absorption wavelength of the resin composition is preferably from 200 to 460 nm. As used herein the term “resin composition” also means and includes a “composition for the formation of a resin” (resin precursor composition).

A resin composition curable by the action of an active energy ray (active-energy-ray-curable resin composition) for the formation of the hologram layer should have certain flexibility so as to satisfactorily conform to shrink processing and, in contrast, should have certain rigidity or hardness so as keep its dimensions to maintain the hologram. Such an active-energy-ray-curable resin composition which has satisfactory flexibility and satisfactory rigidity in good balance and is usable in the shrinkable label herein is a radically polymerizable (radically curable) resin composition containing one or more acrylic monomers and one or more bifunctional or higher-functional urethane acrylates.

### (Radically Curable Resin Composition)

The resin composition radically curable by the action of an active energy ray (hereinafter referred to as “radically curable resin composition”) for the formation of the hologram layer in the shrinkable label includes one or more acrylic monomers and one or more bifunctional or higher-functional urethane acrylates as essential components.

Though not limited, acrylic monomers for use in the radically curable resin composition may be those used as monomer components of known or common acrylic ultraviolet-ray-curable inks (UV inks). Exemplary acrylic monomers include alkyl(meth)acrylates such as methyl(meth)acrylates, ethyl(meth)acrylates, propyl(meth)acrylates, isopropyl(meth)acrylates, butyl(meth)acrylates, isobutyl(meth)acrylates, s-butyl(meth)acrylates, t-butyl(meth)acrylates, hexyl(meth)acrylates, octyl(meth)acrylates, 2-ethylhexyl(meth)acrylates, isononyl(meth)acrylates, decyl(meth)acrylates, and dodecyl(meth)acrylates, of which alkyl(meth)acrylates whose alkyl moiety having 1 to 12 carbon atoms are preferred; carboxyl-containing polymerizable unsaturated compounds such as (meth)acrylic acids, crotonic acid, itaconic acid, fumaric acid, and maleic acid, and anhydrides of them; and hydroxyl-containing (meth)acrylates such as 2-hydroxymethyl(meth)acrylates, 2-hydroxypropyl(meth)acrylates, 3-hydroxypropyl(meth)acrylates, 6-hydroxyhexyl(meth)acrylates, diethylene glycol mono(meth)acrylates, and dipropylene glycol mono(meth)acrylates, of which hydroxyalkyl(meth)acrylates whose alkyl moiety having 1 to 8 carbon atoms are preferred.

The radically curable resin composition may further contain one or more polymerizable unsaturated compounds as monomer components according to necessity, in addition to the acrylic monomers. Exemplary polymerizable unsaturated compounds as additional monomer components include cycloalkyl(meth)acrylates such as cyclohexyl(meth)acrylates; (meth)acrylamide derivatives such as N-methylol(meth)acrylamides, N-butoxymethyl(meth)acrylamides, N,N-dimethyl(meth)acrylamides, and N,N-diethyl(meth)acrylamides; dialkylaminoalkyl(meth)acrylates such as dimethylaminoethyl(meth)acrylates, diethylaminoethyl(meth)acrylates, dipropylaminoethyl(meth)acrylates, dimethylaminopropyl(meth)acrylates, and dipropylaminopropyl(meth)acrylates; styrenic compounds such as styrene, vinyltoluene, and α-methylstyrene; vinyl esters such as vinyl acetate and vinyl propionate; vinyl halides such as vinyl chloride; vinyl ethers such as methyl vinyl ether; cyano-containing vinyl compounds such as (meth)acrylonitriles; and olefins or dienes such as ethylene and propylene.

As used herein, “bifunctional or higher-functional urethane acrylates” are not included in the acrylic monomers; but monofunctional urethane acrylates may be used as the acrylic monomers.

Commercially available products can be used as the acrylic monomers. Examples thereof include inks containing acrylic monomers, such as “FD TC OP Varnish VC” supplied by Toyo Ink Mfg. Co., Ltd.; and “UV Flexographic Varnish FV-2” and “UV LTP FL OP Varnish” both supplied by T&K TOKA Co., Ltd.

The radically curable resin composition contains one or more bifunctional or higher-functional urethane acrylates (including urethane methacrylates) as essential components. The urethane acrylates should have two or more (meth)acryloyl groups per one molecule. The number of (meth)acryloyl groups per one molecule is preferably from two to four, and more preferably two. The urethane acrylates are compounds each including a polyol component, an isocyanate component, and an acrylate component.

The acrylate component is a hydroxyl-containing (meth)acrylate, and specific examples thereof include 2-hydroxymethyl(meth)acrylates, 2-hydroxyethyl(meth)acrylates, 2-hydroxypropyl(meth)acrylates, 3-hydroxypropyl(meth)acrylates, and 6-hydroxyhexyl(meth)acrylates. The isocyanate component can be chosen from known aromatic, aliphatic, and alicyclic diisocyanates. Each of different diisocyanates can be used alone or in combination. Exemplary diisocyanates include tolylene diisocyanate, 4,4-diphenylmethane diisocyanate, 1,3-phenylene diisocyanate, hexamethylene diisocyanate, xylylene diisocyanate, 1,5-naphthalene diisocyanate, and isophorone diisocyanate. Where necessary, one or more of the diisocyanates may be used in combination typically with any of trifunctional or higher-functional polyisocyanates and adducts of such polyisocyanates.

Examples of the polyol compound (polyol component) are known diols including low-molecular-weight glycols such as ethylene glycol, diethylene glycol, 1,3-propanediol, propylene glycol, butanediols (e.g., 1,3-butanediol and 1,4-butanediol), 1,6-hexanediol, and cyclohexanedimethanol; polyether dials such as polyethylene glycol, polypropylene glycol, polytetramethylene glycol, and poly(tetramethylene glycol)-polycaprolactone copolymers; polyester diols each prepared form a diol (e.g., propylene glycol, butanediol, or hexanediol) and a dibasic acid (e.g., adipic acid, sebacic acid, azelaic acid, isophthalic acid, terephthalic acid, or fumaric acid); and lactone diols such as polycaprolactone polyols, polyvalerolactone polyols, and lactone-block-copoly-polyols. Where necessary, one or more trifunctional or higher-functional polyol compounds may be used in combination with one or more of the dials.

The urethane acrylate can be any of commercially available products, such as “Aronix M-1210” supplied by Toagosei Co., Ltd.; “KAYARAD UX-6101” supplied by Nippon Kayaku Co., Ltd.; and “Art Resin UN-9000PEP” supplied by Negami Chemical Industrial Co., Ltd.

The ratio (weight ratio) of the acrylic monomers to the bifunctional or higher-functional urethane acrylates [(acrylic monomers):(bifunctional or higher-functional urethane acrylates)] in the radically curable resin composition is from 95:5 to 45:55, preferably from 85:15 to 50:50, and more preferably from 75:25 to 60:40. If the radically curable resin composition contains acrylic monomers in an amount of more than 95 percent by weight based on the total amount of the acrylic monomers and the bifunctional or higher-functional urethane acrylates, a cured article (cured film) formed from the radically curable resin composition may show insufficient flexibility and insufficient conformity to shrink processing, and this may cause “ink cracking” upon shrink processing to thereby cause whitening of the hologram layer. In contrast, the radically curable resin composition, if containing bifunctional or higher-functional urethane acrylates in an amount of more than 55 percent by weight, may be cured at a low speed to thereby adversely affect the productivity. In addition, the resulting cured article may have insufficient rigidity, and the hologram may be lost upon shrink processing and/or the hologram layer may not uniformly shrink upon shrink processing.

Though not critical, the total amount of the acrylic monomers and the bifunctional or higher-functional urethane acrylates in the radically curable resin composition is preferably from 60 to 99 percent by weight, more preferably from 65 to 96 percent by weight, and furthermore preferably from 70 to 95 percent by weight, based on the total amount of the radically curable resin composition. These ranges are preferred from the viewpoints typically of coatability and curability.

The radically curable resin composition preferably further contains one or more initiators for polymerization by the action of an active energy ray (hereinafter referred to as “photopolymerization initiator(s)”) so as to be curable by the action of an active energy ray. Though not limited, photopolymerization initiators for use herein are preferably photoradical polymerization initiators. Exemplary photoradical polymerization initiators include, but are not limited to, benzoin, benzoin alkyl ethers, benzil ketals, acetophenone, α-hydroxycyclohexyl phenyl ketone, acetophenone derivatives, benzil, benzophenone, benzophenone derivatives, α-acyloxime esters, thioxanthone derivatives, anthraquinone derivatives, and aromatic peroxyesters. Each of different photopolymerization initiators may be used alone or in combination. Among them, α-hydroxycyclohexyl phenyl ketone is especially preferred for the improvements in reactivity and compatibility (miscibility) and for the reduction of odor. Though not critical, the content of photoradical polymerization initiators is preferably from 0.5 to 7 percent by weight, and more preferably from 1 to 5 percent by weight, based on the total amount of the resin composition.

The radically curable resin composition preferably contains one or more release agents (parting agents) from the viewpoint of more satisfactory release from a transfer hologram (hologram to be transferred) such as hologram foil. The release agents can be chosen from known or common release agents such as silicone compounds, fluorine compounds, and long-chain alkyl compounds. Among them, silicone compounds (silicone release agents) are preferred. The amount of the release agents is preferably from 0.1 to 3 parts by weight, and more preferably from 0.5 to 2.5 parts by weight, per 100 parts by weight of the total amount of the acrylic monomers and the bifunctional or higher-functional urethane acrylates. If the amount of release agents is less than 0.1 part by weight, the resulting resin layer (cured layer) may not be smoothly released from the hologram foil after transfer, and this may cause the breakage of the foil or cause not satisfactorily sharp expression of the hologram. If it exceeds 3 parts by weight, the oil (release agent) on the surface of the label may deposit on process components to cause process contamination, and/or the label may have an excessively smooth surface to cause problems such as blocking.

Though not limited, silicone compounds for use as the release agents may be polysiloxanes having a siloxane-bond main chain (principal chain). Examples thereof include straight silicone compounds having no other substituents than methyl group and phenyl group, such as dimethyl silicones, methyl phenyl silicones, and methyl hydrogen silicones; and modified silicone compounds having one or more substituents other than methyl group and phenyl group in their side chains or terminals.

Exemplary substituents in the modified silicones include epoxy group, fluorine atom, amino group, carboxyl group, aliphatic hydroxyl group (alcoholic hydroxyl group), aromatic hydroxyl group (phenolic hydroxyl group), (meth) acryloyl-containing substituents, and substituents having a polyether chain. Exemplary modified silicones containing such substituents include epoxy-modified silicones, fluorine-modified silicones, amino-modified silicones, (meth)acrylic-modified silicones, polyether-modified silicones, carboxyl-modified silicones, carbinol-modified silicones, phenol-modified silicones, and diol-modified silicones. The compounds described in PCT International Publication Number WO 2007/007803, for example, can be used as such modified silicone compounds.

The content of a solvent, if contained in the radically curable resin composition, is preferably 5 percent by weight or less, more preferably 1 percent by weight or less, and furthermore preferably substantially zero (i.e., the resin composition contains substantially no solvent), where the solvent is not involved in the reaction and is used mainly as a dispersant. As used herein the term “solvent” refers to one that is generally used typically in inks for gravure printing or flexographic printing so as to improve the coating workability of coating compositions (inks) or the compatibility and dispersibility of components in the coating compositions. Exemplary “solvents” include organic solvents such as toluene, xylenes, methyl ethyl ketone, ethyl acetate, methyl alcohol, ethyl alcohol, isopropyl alcohol, and cyclohexane; and water. Reactive diluents taken into the resin composition after curing are not included in this category (solvents). The radically curable resin composition for use herein can develop satisfactory coatability and dispersibility among components even when containing no solvent and thereby needs a minimum amount of a solvent. This eliminates the need of removing the solvent, allows high-speed production and cost reduction, and reduces the environmental load.

The radically curable resin composition may be a transparent resin composition containing no pigment component, or a resin composition colored by one or more colorants within ranges not impeding development of a sharp holographic expression (holographic display). The colorants can be chosen from pigments and dyestuffs generally used in printing inks without limitation. Among them, pigments are preferably used. Exemplary pigments usable herein include organic or inorganic coloring pigments including cyan (blue) pigments such as copper phthalocyanine blue; red pigments such as condensed azo pigments; yellow pigments such as azo lake pigments; carbon black; aluminum flake; and mica. One or more pigments according to the intended use may be suitably chosen from among them. Extender pigments can also be used as the pigments, for the purpose typically of gloss modification. Exemplary extender pigments include alumina, calcium carbonate, barium sulfate, silica, and acrylic beads. The amount of such pigments is preferably from 1 to 20 parts by weight, per 100 parts by weight of the total amount of the acrylic monomers and the bifunctional or higher-functional urethane acrylates. The range is preferred from the viewpoint of not impeding holographic expression.

In addition to the above components, the radically curable resin composition may further contain any of other resin components and additives such as sensitizers, dispersants, antioxidants, flavors, deodorants, stabilizers, and lubricants within ranges not adversely affecting the advantages of the present invention. These are added for the purpose of imparting other function(s) to the resin composition.

Though not critical, when to be applied by gravure printing, the viscosity (23±2° C.) of the radically curable resin composition is preferably from 10 to 2000 millipascal second (mPa·s), and more preferably from 20 to 1000 mPa·s. The radically curable resin composition, if having a viscosity of more than 2000 mPa·s, may not be satisfactorily applied by gravure printing. In contrast, the radically curable resin composition, if having a viscosity of less than 10 mPa·s, may become insufficiently stable during storage and may often suffer from problems such as sedimentation of additives. The viscosity of the resin composition can be controlled, for example, by adjusting or modifying the compounding ratios of respective components and/or by adding thickeners or viscosity decreasers. As used herein the term “viscosity” refers to a value as determined with a type E viscometer (cone-and-plate rotating viscometer) at a temperature of 23±2° C. and at a number of revolutions of the cylinder of 50 in accordance with Japanese Industrial Standards (JIS) Z 8803, unless otherwise specified.

When to be applied by flexographic printing, the viscosity of the radically curable resin composition is preferably from 10 to 50 seconds as determined with a Zahn cup #3 (supplied by Rigo Co., Ltd.).

The radically curable resin composition is prepared by blending or mixing the above-mentioned components such as acrylic monomers, urethane acrylates, and, according to necessity, photopolymerization initiators, release agents, and other additives. Exemplary devices for the mixing include mixers such as butterfly mixer, planetary mixer, pony mixer, dissolver, tank mixer, homomixer, and homodisperser; and mills such as roll mill, sand mill, ball mill, bead mill, and line mill; and kneaders. The mixing time (residence time) in the mixing is preferably from 10 to 120 minutes. The resulting resin composition may be subjected to filtration before use, where necessary.

The radically curable resin composition for the formation of the hologram layer is cured by the action of an active energy ray to give a cured article (cured resin article). The cured article has a structure in which the acrylic monomer component and the urethane acrylate component are copolymerized with each other. The cured article therefore has higher flexibility and higher conformity to shrink processing than a cured resin article made from acrylic monomer alone, and does not suffer from the cracking of the cured resin layer (hologram layer) (so-called “ink cracking”) even when undergoing relatively large shrinkage and deformation. The cured article also has a constant proper rigidity (hardness) by controlling the ratio of the acrylic monomers to the urethane acrylates and thereby does not suffer from loss of the once-formed hologram typically upon shrink processing. The cured article does not suffer from whitening upon shrinkage but provides a satisfactory holographic expression even when used in a shrinkable label which will undergo relatively large shrinkage and deformation. In contrast, if such a cured resin article becomes excessively flexible or soft, it may suffer from the loss of the hologram typically upon shrink processing.

### [Shrinkable Film]

The shrinkable film for use in the shrinkable label is a layer which serves as a base of the label and which bears strength properties and shrinking properties. One or more resins for use in the shrinkable film can be chosen suitably according typically to required properties and cost. Exemplary resins include, but are not limited to, polyester resins, olefinic resins, styrenic resins, poly(vinyl chloride)s, polyamide resins, aramids, polyimides, poly(phenylene sulfide)s, and acrylic resins. Above all, the shrinkable film is preferably made from a polyester film, a polystyrenic film, or a laminated film of these films. Exemplary polyester resins usable herein include poly(ethylene terephthalate) (PET) resins, poly(ethylene-2,6-naphthalenedicarboxylate)s (PENs), and poly(lactic acid)s (PLAs), of which poly(ethylene terephthalate) (PET) resins are preferred. Preferred exemplary styrenic resins include regular polystyrenes, styrene-butadiene copolymers (SBSs), and styrene-butadiene-isoprene copolymers (SBISs).

The shrinkable film for use herein may be a single-layer film, or a multilayer film including two or more film layers according typically to required properties and intended use. When it is a multilayer film, the multilayer film may include two or more different film layers made from two or more different resins, respectively.

The shrinkable film is preferably a monoaxially, biaxially, or multiaxially oriented film, so as to exhibit shrinking properties. When the shrinkable film is a multilayer film including two or more film layers, at least one film layer of the multilayer film is preferably oriented. If all the film layers are not oriented, the shrinkable film may not exhibit sufficient shrinking properties. The shrinkable film is often a monoaxially or biaxially oriented film and is generally a film intensively oriented in a film width direction (a direction to be a label circumferential direction). In other words, the shrinkable film is generally a film substantially monoaxially oriented in the width direction.

The shrinkable film may be prepared according to a common procedure such as film formation using a molten material or film formation using a solution. Independently, commercially available shrinkable films are also usable herein. Where necessary, the surface of the shrinkable film may have been subjected to a common surface treatment such as corona discharge treatment and/or primer treatment. The lamination of the shrinkable film, if having a multilayer structure, can be performed according to a common procedure such as coextrusion or dry lamination. The orientation of the shrinkable film may be performed by biaxial drawing in a longitudinal direction (lengthwise direction; machine direction (MD)) and in a width direction (cross direction; transverse direction (TD)) or by monoaxial drawing in a longitudinal or cross direction. The drawing can be performed according to any of roll drawing, tenter drawing, or tube drawing. The drawing is often performed by conducting drawing in a longitudinal direction according to necessity and thereafter drawing in a cross direction each at a temperature of from about 70° C. to about 100° C. The draw ratio in the longitudinal drawing may be from about 1.01 to about 1.5 times, and preferably from about 1.05 to about 1.3 times. The draw ratio in the crosswise drawing may be from about 3 to about 6 times, and preferably from about 4 to about 5.5 times.

Though not critical, the thickness of the shrinkable film is preferably from 10 to 100 μm, more preferably from 20 to 80 μm, and furthermore preferably from 30 to 60 μm. The shrinkable film may be a three-layer film including a core layer and surface layers. In this case, the ratio in thickness among the core layer and the surface layers [(surface layer)/(core layer)/(surface layer)] is preferably from 1/2/1 to 1/10/1.

The shrinkable film for use in the shrinkable label is preferably one having a relatively small shrinkage stress and a relatively low shrinkage rate. These conditions are preferred from the viewpoints of maintaining the shape of the hologram upon shrink processing and of ensuring the conformity of the hologram layer to shrink processing. To satisfy these conditions, the shrinkable film is preferably a multilayer film including at least one layer of polyester resin and at least one layer of styrenic resin. Among such films, a multilayer shrinkable film including a styrenic resin core layer, and polyester resin surface layers is especially preferred. This multilayer shrinkable film is preferred because the polyester resin shows good adhesion to the hologram layer, and the styrenic resin exhibits satisfactory shrinking properties. Such shrinkable films are also commercially available, and examples thereof include multilayer films including polyester resin surface layers and a styrenic resin core layer, such as “DL” supplied by Mitsubishi Plastics, Inc. and “HGS” supplied by GUNZE Limited; polystyrenic films such as “BONSET” supplied by CI Kasei Co., Ltd.; and polylactic acid) films such as “ECOLOJU” supplied by Mitsubishi Plastics, Inc.

Though not critical, the percentage of thermal shrinkage (in hot water at 70° C. for 10 seconds) of the shrinkable film for use herein in its principal orientation direction is preferably from 10% to 30%, and more preferably from 15% to 25%. Also though not critical, the percentage of thermal shrinkage (in hot water at 80° C. for 10 seconds) of the shrinkable film in its principal orientation direction is preferably from 30% to 70%, and more preferably from 35% to 65%. If the shrinkable film has a percentage of thermal shrinkage in its principal orientation direction exceeding the above range, the hologram layer may not satisfactorily conform to shrink processing and may cause whitening and/or unsatisfactory expression of the hologram. If the shrinkable film has a percentage of thermal shrinkage in its principal orientation direction less than the above range, the resulting label may not satisfactorily fit the dimensions of an article to be attached, and the resulting container with the label may not be well finished. As used herein the term “principal orientation direction” refers to a direction in which the drawing process has been mainly performed (i.e., a direction in which the percentage of thermal shrinkage is largest) and, when the shrinkable label is a tubular shrinkable label, it is generally a width direction of the film.

The percentage of thermal shrinkage (80° C. for 10 seconds) of the shrinkable film in a direction perpendicular to the principal orientation direction is preferably from about −3% to about 15%, though not critical.

The transparency of the shrinkable film for use herein, when being a transparent film, is preferably less than 10, more preferably less than 5.0, and furthermore preferably less than 2.0, in terms of haze (%) determined in accordance with JIS K 7105. The shrinkable film, if having a haze of 10 or more, may cloud a print and thereby cause insufficient decorativeness when the print is to be seen through the shrinkable film.

### [Shrinkable Label]

The shrinkable label according to an embodiment of the present invention is prepared by forming a hologram layer on the shrinkable film through curing of the radically curable resin composition. The hologram layer may be formed mainly through the following steps (i) to (iv) of: (i) applying the radically curable resin composition to the shrinkable film; (ii) laying a transfer hologram over the resin composition layer formed by the step (i); (iii) curing the resin composition layer by the action of an active energy ray (to give a “cured resin layer”); and (iv) removing the transfer hologram. The steps (i) to (iv) are preferably performed as a series of steps with the applying step (coating step) from the viewpoint of productivity. Though not critical, the process speed herein is preferably from 20 to 150 meters per minute (m/min), and more preferably from 25 to 100 m/min.

Preferred procedures to apply the resin composition to the shrinkable film in the step (i) include gravure printing, flexographic printing, serigraph, and rotary letterpress, of which gravure printing and flexographic printing are more preferred. These procedures are preferred from the viewpoints typically of cost, productivity, and decorativeness of the resulting print. The coating step may be performed at any stage (time) not critical and may be performed as an in-line coating or an off-line coating. The in-line coating is provided during the production processes of the shrinkable film, for example, before drawing or after monoaxial longitudinal drawing. The off-line coating is provided after the formation of the shrinkable film. Among them, the off-line coating is preferred from the viewpoints of productivity and workability such as curing workability.

The transfer hologram for use in the step (ii) may be in any form such as a roll or film, but it is preferably one in a film form, such as hologram master film or hologram foil, from the viewpoint of convenience. The laying (lamination) of, for example, a hologram master film over the resin composition layer may be performed according to or using a device or procedure generally used in lamination of such films, such as nip roller or air blast. Among them, air blast is preferred from the viewpoint of suppressing the occurrence of shearing stress upon overlaying (lamination).

In the step (iii), curing of the (uncured) resin composition layer is performed through active-energy-ray curing using a device such as ultraviolet (UV) lamp, ultraviolet light emitting diode (UV LED), or ultraviolet laser. From the viewpoint of curability, the active energy ray to be applied is preferably an ultraviolet ray (near-ultraviolet ray) having a wavelength of from 200 to 460 nm; and the application (irradiation) is preferably performed at an irradiation intensity of from 150 millijoules per square centimeter (mJ/cm²) to 1000 mJ/cm² for an irradiation time of from 0.1 to 3 seconds, while these ranges may vary depending on the formulation of the resin composition and are not critical.

The hologram layer (cured resin layer) is preferably provided as a surface-most layer (such as an outermost layer or innermost layer) in the shrinkable label. Exemplary multilayer structures of the shrinkable label include, but are not limited to, (hologram layer)/(shrinkable film layer)/(print layer); (hologram layer)/(print layer)/(shrinkable film layer)/(print layer); and (hologram layer)/(anchor coat layer)/(shrinkable film layer)/(print layer). In addition, a print layer may be partially provided over the surface hologram layer. The hologram layer for use herein has good adhesion with the shrinkable film and thereby exhibits satisfactory activities even when it is arranged directly on the surface of the shrinkable film. The lamination structure, however, is not limited thereto, and the hologram layer may be provided over the shrinkable film with the interposition of one or more other layers such as adhesive layer.

The thickness of the hologram layer in the shrinkable label is preferably from 0.3 to 5 μm, and more preferably from 0.5 to 3 μm, though not critical. The hologram layer, if having a thickness of more than 5 μm, may cause curing failure and/or shrinking failure. In contrast, when the hologram layer is formed to have a thickness of less than 0.3 μm, the hologram layer may not have depressions and protrusions in sufficient heights as a result of holographic processing to form a hologram, and the resulting hologram may not be formed stably.

The shrinkable label may further include one or more layers such as print layers, in addition to the shrinkable film and the hologram layer. Exemplary print layers include design print layers which indicate, for example, a product name, an illustration, a design, or handling precautions; and white backing print layers. Such a print layer is formed by applying a layer of printing ink, and, where necessary, drying and/or curing the applied layer. The printing ink herein contains a binder resin, a pigment, and, where necessary, a solvent as components. Though not critical, the thickness of the print layer (as a single layer) is preferably from 0.1 to 15 μm, and more preferably from 0.5 to 10 μm. The shrinkable label may include such a print layer partially and/or may include two or more print layers. The print layer(s) may be formed according to a known or common coating procedure not limited, but is preferably formed typically through gravure printing or flexographic printing. The printing step is preferably performed before the step of forming the hologram layer, through not limited thereto. When a print layer is to be formed partially over the hologram layer, the printing step is performed after the step of forming the hologram layer.

The shrinkable label may further include one or more other layers according to necessity. Exemplary other layers include protective layer, adhesive layer, ultraviolet-absorbing layer, overlaminate layer, anchor coat layer, primer coat layer, nonwoven fabric layer, and paper layer.

The shrinkage stress (primary shrinkage stress) (in hot water at 80° C.) of the shrinkable label in its principal orientation direction is preferably from 1.0 to 6.0 N/mm², and more preferably from 1.5 to 5.0 N/mm². The shrinkable label, if having a shrinkage stress of more than 6.0 N/mm², may not satisfactorily conform to shrinking and may thereby suffer from whitening (ink cracking). The shrinkable label, if having a shrinkage stress of less than 1.0 N/mm², may not sufficiently fit the dimensions of an article to be applied upon shrink processing and may not be well finished, or the ink coat may not sufficiently shrink to thereby suffer from shrinkage failure such as wrinkles or curls. The “thermal shrinkage stress (primary shrinkage stress)” herein is a maximum value of shrinkage stress as determined while immersing 80% of a test piece of the shrinkable label in hot water at 80° C. for 10 seconds and measuring shrinkage stress with a tensile tester.

The shrinkage rate (in hot water at 80° C.) of the shrinkable label in its principal orientation direction is preferably from 1% to 20% per 0.2 second, and more preferably from 2% to 15% per 0.2 second. The shrinkable label, if having a shrinkage rate of more than 20% per 0.2 second, may not satisfactorily conform to shrinking and may thereby suffer from whitening (ink cracking). The shrinkable label, if having a shrinkage rate of less than 1% per 0.2 second, may not be produced with good productivity, because it may take much time to perform shrink processing. The shrinkage stress and the shrinkage rate of the shrinkable label are close to those of the shrinkable film contained therein.

The thickness of the shrinkable label is preferably from 10 to 150 μm, and more preferably from 20 to 120 μm, though not critical.

The shrinkable label is not limited in its form (shape) and can be, for example, a tubular label or a wrapping label. However, the shrinkable label is preferably a shrinkable label of tubular form (tubular shrinkable label; cylindrical shrinkable label) so as to exhibit the advantages of the present invention. Specifically, the shrinkable label according to the present invention provides a beautiful holographic expression even when it shrinks and deforms to a large extent as a result of shrink processing. In this connection, there are common labels having a hologram layer formed by using a regular active-energy-ray-curable resin composition other than the resin composition for use in the present invention. These common labels are difficult to be used as tubular labels, although some of them are usable as wrapping labels in which the labels shrink and deform to a relatively small degree.

### [Other Processings]

The shrinkable label, when used as a tubular shrinkable label, is formed into a round tube (cylinder) so that the principal orientation direction (generally, a width direction of the sheet) is to be a circumferential direction of the label. Specifically, a long continuous shrinkable label is formed into a tube, and a solvent, such as tetrahydrofuran (THF), and/or an adhesive (these components are hereinafter referred to as “solvent or another component”) is applied to an inner surface of one lateral end of the label to form a band about 2 to 4 mm wide in a longitudinal direction. The label is then cylindrically wound so that the portion where the solvent or another component is applied is laid over the outer surface of the other lateral end of the label at a position of 5 to 10 mm inside from the other lateral end, affixed and adhered (center-sealed). Thus, the tubular shrink label is obtained as a continuous long tubular sheet. In this process, it is desirable that neither hologram layer nor print layer is arranged in a portion where the solvent or another component is applied (center-seal portion) so that two adjacent portions of the base shrinkable film are directly bonded with each other in the portion.

The shrinkable label may have perforations for tearing the label. In this case, perforations with predetermined lengths and intervals (pitches) may be formed in a longitudinal direction. The perforations can be arranged according to a common procedure. They can be arranged, for example, by pressing a disk-like blade peripherally having cutting edges and non-cutting portions alternately, or by using laser. The step of arranging perforations can be carried out as appropriate in a suitable stage, such as after the printing step, or before or after the step of processing the label to form a tubular label. Though may be arranged on the hologram layer, the perforations are preferably arranged in a portion of the base shrinkable film where the hologram layer is not provided.

[Container with Label]

The shrinkable label is attached to a container to give a container with the label. Exemplary containers for use in the container with the label include soft-drink bottles such as PET plastic bottles; home-delivery milk containers; containers for foodstuffs such as seasonings; alcoholic drink bottles; containers for pharmaceutical preparations; containers for chemicals such as detergents and aerosols (sprays). Preferred materials for the container include, but are not limited to, plastics such as poly(polyethylene terephthalate)s (PETs); and paper. Though not critical, the container preferably has a cylindrical or rectangular bottle shape.

The way to attach the shrinkable label to the container may be, but is not limited to, the following procedure. When the shrinkable label is a tubular shrinkable label, a continuous tubular shrinkable label is cut, the cut label is attached to a predetermined container, is allowed to shrink through heat treatment to come into intimate contact with the container, and thereby yields a container with the label. More specifically, the continuous long tubular shrinkable label is fed to an automatic labeling machine (shrink labeler), cut to a required length, fitted onto a container filled with a content, subjected to thermal shrinkage by allowing the article to pass through a hot-air tunnel or steam tunnel at a predetermined temperature or by heating the article with radial heat such as infrared rays to come into intimate contact with the container, and thus yields the container with the label. Though being shrinkable by the application of hot air (at 60° C. to 300° C.), the shrinkable label is preferably allowed to shrink by the application of steam (water vapor), because it is desirable to allow the label to shrink uniformly and relatively gradually. The heating treatment is preferably performed at a temperature of from 60° C. to 100° C., and more preferably from 65° C. to 95° C. Upon the attachment to the container, a portion of the shrinkable label where the hologram layer is formed (hologram-formed portion) thermally shrinks preferably by a rate of from about 3% to about 25%, and more preferably by a rate of from about 5% to about 20%.

### [Methods for Determination of Properties and Evaluation of Effectiveness]

(1) Percentage of Thermal Shrinkage (in Hot Water at 70° C. for 10 Seconds) and Percentage of Thermal Shrinkage (in Hot Water at 80° C. for 10 Seconds)

A method for measuring a percentage of thermal shrinkage (in hot water at 70° C. for 10 seconds) will be described below. A percentage of thermal shrinkage (in hot water at 80° C. for 10 seconds) can be measured by the following method, except for changing the temperature of the hot water from 70° C. to 80° C.

A square sample piece of 50 mm in a principal orientation direction and 50 mm in a perpendicular direction to the principal orientation direction was prepared from a shrinkable film to be tested.

The sample piece was subjected to a heat treatment (under no load) in hot water at 70° C. for 10 seconds, the sizes (in a width direction) of the sample before and after the heat treatment were read out, and a percentage of thermal shrinkage was calculated according to the following formula. The test was repeated a total of five times, and the average of five data was defined as the percentage of shrinkage.

The principal orientation direction of shrinkable films (shrinkable labels) prepared according to the examples and comparative examples below is the width direction of the films.

Percentage of Thermal Shrinkage(%)=(L₀−L₁)/L₀×100

L₀: Size (in the principal orientation direction) of the sample before the heat treatment;

L₁: Size (in the same direction as L₀) of the sample after the heat treatment

The determination method of the percentage of thermal shrinkage in the principal orientation direction has been described above. The percentage of thermal shrinkage in a perpendicular direction to the principal orientation direction can be calculated according to the determination method, except for measuring sizes in a perpendicular direction to the principal orientation direction.

When a principal orientation direction is unknown, the principal orientation direction may be determined by measuring percentages of thermal shrinkage in different directions at intervals typically of 10° and defining a direction, in which the percentage of shrinkage has a maximum, as the principal orientation direction.

(2) Shrinkage Stress (in Hot Water at 80° C.)

A roughly rectangular sample piece of 200 mm in a principal orientation direction and 15 mm in a perpendicular direction to the principal orientation direction was sampled from each of the shrinkable labels prepared according to the examples and comparative examples. The sample piece was secured by chucks of a tensile tester (supplied by Shimadzu Corporation, “Autograph AGS-50G”, capacity of load cell: 500 N) at a chuck-interval of 100 mm so that the principal orientation direction stands the tensile direction. While maintaining the chuck interval at 100 mm, the sample piece was immersed in hot water at 80° C. for 10 seconds so that the sample piece in a portion from the lower end up to 80 mm of the 100-mm chuck interval was immersed in the hot water. A shrinkage stress (N/mm²) generated in this process was measured, and the maximum value of the shrinkage stress was defined as the shrinkage stress (primary shrinkage stress) of the sample.

(3) Shrinkage Rate (in Hot Water at 80° C.)

A strip sample piece of 100 mm in the principal orientation direction and 5 mm in a perpendicular direction to the principal orientation direction was sampled for measurements from each of the shrinkable labels prepared according to the examples and comparative examples.

The sample piece was immersed in a hot bath at 80° C., how the size in its principal orientation direction (initial measurement length: 88 mm) changed with time during immersion was measured (sampling time (interval): 0.1 second), from which how the percentage of thermal shrinkage changed with time was calculated. The rate of change (unit: percentage (%) per 0.2 second) of the percentage of thermal shrinkage with respect to the time was calculated from measured percentages of thermal shrinkage at three subsequent measurement points, and the maximum value thereof was defined as the “shrinkage rate (in hot water at 80° C.)” of the sample.

(4) Surface Curability (Initial Tack Test)

In the procedures of the examples and comparative examples, a curing process of a resin composition layer was performed by the application of an ultraviolet ray (ultraviolet irradiation process speed: 70 m/min), and immediately after the curing process, the surface of a cured resin layer was touched by finger. Whether the resin composition remaining uncured stuck to the finger was visually observed, and the surface curability (initial tack test) was evaluated according to the following criteria: when no resin composition stuck to the finger, the sample was evaluated as having good surface curability (Good); and when the resin composition stuck to the finger, the sample was evaluated as having poor surface curability (Poor).

(5) Adhesion (Tape Peel Test)

Tests were performed in accordance with Japanese Industrial Standards (JIS) K 5600, except for not providing cross cuts on samples. Specifically, a Nichiban Tape (18 mm in width) was affixed to the surface of the hologram layer of each of the shrinkable labels prepared according to the examples and comparative examples, the tape was thereafter peeled off at an angle of 90 degrees, and how much area the hologram layer remained on the label was observed in a region of 5 mm long and 5 mm wide. The adhesion (adhesiveness) of the sample was determined according to the following criteria:

90% or more of the hologram layer remains: Good adhesion (Good)

80% or more and less than 90% of the hologram layer remains: Somewhat poor adhesion but at usable level (Tolerable)

Less than 80% of the hologram layer remains: Poor adhesion (Poor)

(6) Shrinkage Whitening Test (Conformity to Processing) (Shrinking Heat Treatment)

A strip sample piece of 100 mm in length and 50 mm in width was sampled from each of the shrinkable labels prepared according to the examples and comparative examples so that the principal orientation direction (width direction of the label) be the longitudinal direction of the sample piece.

The sample was secured at both ends (at a distance of 100 mm) in its longitudinal direction by a jig. The jig was configured to secure the sample piece at an interval of 80 mm, and the secured sample piece was therefore loose before heat treatment. The sample secured at both ends by the jig was subjected to a heat treatment (heat shrink processing) by immersing the same in hot water at 90° C. for 10 seconds so as to thermally shrink by 20%.

### (Evaluation)

The sample after the heat shrink processing was evaluated according to the following criteria:

The sample does not suffer from whitening: Good process conformity (Good)

The sample slightly suffers from whitening: Usable level (Tolerable)

The sample suffers from whitening: Poor process conformity (Poor)

(7) Holographic Expressivity

Each of the shrinkable labels prepared according to the examples and comparative examples was thermally shrunk by 10% or 20% by the procedure of the shrinkage whitening test, the resulting pattern was visually observed, and the holographic expressivity of each sample was evaluated according to the following criteria.

To thermally shrink the sample by 10%, the jig interval in the heat shrink processing in the shrinkage whitening test was changed to 90 mm.

A clear optical interference pattern (holographic pattern) is observed: Good holographic expressivity (Good)

An optical interference pattern is observed but at a low brightness: Usable level (Tolerable)

An optical interference pattern is not clearly observed: Poor holographic expressivity (Poor)

### EXAMPLES

The present invention will be illustrated in further detail with reference to several examples below. It should be noted, however, that these examples are never construed to limit the scope of the present invention. Table 1 shows the formulations (weight ratios) of a component A and a component B in resin compositions; and evaluations of the resin compositions and shrinkable labels each prepared according to the examples and comparative examples.

### Examples 1

### Active-Energy-Ray-Curable Resin Composition

A radically curable resin composition was prepared by blending the “UV LTP FL OP Varnish” (trade name; supplied by T&K TOKA Co., Ltd.) and the “Aronix M-1210” (trade name; supplied by Toagosei Co., Ltd.). The “UV LTP FL OP Varnish” is an ink containing 95 percent by weight of an acrylic monomer, and further containing a radical photopolymerization initiator and a release agent. The “Aronix M-1210” is a product containing 35 percent by weight of an acrylic monomer and 65 percent by weight of a bifunctional urethane acrylate. The blending was performed so that the weight ratio of the acrylic monomer(s) (hereinafter referred to as “component A”) to the bifunctional urethane acrylate (hereinafter referred to as “component B”) be the weight ratio given in Table 1. Namely, the blending was performed so that the weight ratio of the “UV LTP FL OP Varnish” to the “Aronix M-1210” be 90:10. No solvent was used herein.

### (Shrinkable Film)

A shrinkable film used herein as a base film was a multilayer shrinkable film (supplied by Mitsubishi Plastics, Inc. under the trade name “DL”). The multilayer shrinkable film “DL” has a thickness of 40 μm, a percentage of thermal shrinkage (70° C. for 10 seconds) of 20.3%, and a percentage of thermal shrinkage (80° C. for 10 seconds) of 37.1% and includes polyester resin surface layers and a styrenic resin core layer.

### (Shrinkable Label)

The radically curable resin composition was applied to one side of the shrinkable film through entire gravure printing to give a resin composition layer 3 μm thick. The gravure printing was performed by using a bench gravure printing machine (supplied by Nissho Gravure Co., Ltd. under the trade name “GRAVO PROOF MINI”) and a photogravure cylinder (gravure plate) of 80 lines, with a plate depth of 27 μm.

Next, a hologram transfer foil (supplied by Coburn Japan Corporation under the trade name “Hologram Transparent OPP Laminate Film”) was laid over the resin composition layer. Subsequently, the resin composition layer was cured by applying light to the resin composition layer side under conditions of a conveyor speed of 70 m/min and at 240 watts per centimeter (W/cm) using an ultraviolet irradiator (supplied by Fusion UV Systems Japan KK under the trade name “LIGHT HAMMER 10”; output 100%, D valve). Thereafter the hologram transfer foil was removed to give a shrinkable label having a hologram layer. The shrinkable label had a shrinkage rate (in hot water at 80° C.) of 5.6% per 0.2 second and a shrinkage stress of 4.7 N/mm², wherein the shrinkage stress was determined while immersing 80% of a test piece of the shrinkable label in hot water at 80° C. for 10 seconds.

In the above procedure, the process speeds were 50 m/min in the printing process, 70 m/min in the curing process, and 50 m/min in the process of laminating and removing the hologram foil.

The above-prepared shrinkable label (having a label thickness of 42 μm and a hologram layer thickness of 2 μm) was evaluated on the surface curability (initial tack test), adhesion (tape peel), process conformity (shrinkage whitening test), and holographic expressivity.

As is demonstrated in Table 1, the prepared resin composition and shrinkable label had superior properties.

Independently, the above-prepared shrinkable label was wound into a tube (cylinder) so that the hologram layer faced outward and the width direction of the film stood the circumferential direction. The wound label was center-sealed with tetrahydrofuran (THF), and thereby yielded a tubular shrinkable label. At last, the tubular shrinkable label was attached to a container (supplied by Toyo Seikan Kaisha, Ltd.; 500-ml heat-resistant rectangular PET plastic bottle), heated and shrunk in a steam tunnel at an atmospheric temperature of 90° C. so that the hologram-bearing portion shrunk by 5% to 15%, and thereby yielded a container with a label. The resulting container with the label was well finished.

### Examples 2 to 5

A series of radically curable resin compositions and shrinkable labels was prepared by the procedure of Example 1, except for changing the weight ratio of the component A to the component B as give in Table 1. The shrinkage rates (in hot water at 80° C.) and shrinkage stresses (shrinkage stress as determined while immersing 80% of a test piece of the shrinkable label in hot water at 80° C. for 10 seconds) of the shrinkable labels according to Examples 2 to 5 were close to those of the shrinkable label according to Example 1.

As is demonstrated in Table 1, the prepared resin compositions and shrinkable labels had superior properties. Independently, a series of containers with a label was prepared by the procedure of Example 1 to find that the prepared containers with the label were well finished.

### Comparative Example 1

A radically curable resin composition and a shrinkable label were prepared by the procedure of Example 1, except for not using the component B as shown in Table 1.

As is demonstrated in Table 1, the prepared shrinkable label was inferior in properties.

### Comparative Example 2

A radically curable resin composition and a shrinkable label were prepared by the procedure of Example 1, except for changing the weight ratio of the component A to the component B as given in Table 1.

As is demonstrated in Table 1, the prepared resin composition and shrinkable label were inferior in properties.

In the examples and comparative examples, the weight ratio of the component A to the component B was changed by changing the compounding ratio between the “UV LTP FL OP Varnish” (trade name; supplied by T&K TOKA Co., Ltd.) and the “Aronix M-1210” (trade name; supplied by Toagosei Co., Ltd.). Where necessary, a suitable amount of a radical photopolymerization initiator (supplied by Ciba Specialty Chemicals Corporation under the trade name “IRGACURE 184”) was further added.

TABLE 1

| | | | Example 1 | Example 2 | Example 3 | Example 4 | Example 5 | Com. Ex. 1 | Com. Ex. 2 |
|---|---|---|---|---|---|---|---|---|---|
| Weight ratio between | Component A (acrylic monomer) | | 93 | 80 | 67 | 55 | 48 | 100 | 41 |
| Component A and | Component B (urethane acrylate) | | 7 | 20 | 33 | 45 | 52 | 0 | 59 |
| Component B | | | | | | | | | |
| Evaluations | Surface curability (initial tack | | Good | Good | Good | Good | Good | Good | Poor |
| | test) | | | | | | | | |
| | Adhesion (tape peel test) | | Good | Good | Good | Tolerable | Tolerable | Good | Poor |
| | Whitening upon shrinkage | | Tolerable | Good | Good | Good | Good | Tolerable | Good |
| | (process conformity) | | | | | | | | |
| | Holographic | shrinkage by 10% | Good | Good | Good | Good | Good | Tolerable | Tolerable |
| | expressivity | shrinkage by 20% | Tolerable | Tolerable | Good | Good | Tolerable | Poor | Tolerable |

### INDUSTRIAL APPLICABILITY

The present invention is applicable to a shrinkable label which has a hologram layer and which provides a sharp holographic expression even after shrink processing with relatively large deformation, and it is also applicable to a container with the shrinkable label attached thereto.

1. A shrinkable label comprising a shrinkable film; and a hologram layer present on or above at least one side of the shrinkable film, the hologram layer formed by curing a resin composition, the resin composition being radically curable by the action of an active energy ray and containing 45 to 95 percent by weight of one or more acrylic monomers and 5 to 55 percent by weight of one or more bifunctional or higher-functional urethane acrylates, based on the total amount of the acrylic monomers and the bifunctional or higher-functional urethane acrylates.

2. The shrinkable label according to claim 1, wherein the shrinkable film has a percentage of thermal shrinkage (in hot water at 70° C. for 10 seconds) in its principal orientation direction of from 10% to 30% and has a percentage of thermal shrinkage (in hot water at 80° C. for 10 seconds) in its principal orientation direction of from 30% to 70%.

3. The shrinkable label according to claim 1, wherein the shrinkable label has a shrinkage rate (in hot water at 80° C.) in its principal orientation direction of from 1% to 20% per 0.2 second.

4. The shrinkable label according to claim 1, wherein the shrinkable label has a shrinkage stress in its principal orientation direction of from 1.0 to 6.0 newtons per square millimeter (N/mm²), wherein the shrinkage stress is determined while immersing 80% of a test piece of the shrinkable label in hot water at 80° C. for 10 seconds.

5. The shrinkable label according to claim 1, as a tubular shrinkable label.

6. A container with a label, prepared by placing the shrinkable label according to claim 1 around a container and allowing the shrinkable label to shrink to thereby come into intimate contact with the container.
